(19) United States
(12) Patent Application Publication
(10) Pub. No.: US 2024/0413040 A1
(43) Pub. Date: Dec. 12, 2024

(54) PACKAGE STRUCTURE AND MANUFACTURING METHOD THEREOF

(71) Applicant: JCET GROUP CO., LTD., Jiangsu (CN)

(72) Inventors: Danfeng Yang, Jiangsu (CN); Songhua Xu, Jiangsu (CN); Chen Xu, Jiangsu (CN); Shasha Zhou, Jiangsu (CN)

(73) Assignee: JCET GROUP CO., LTD., Jiangsu (CN)

(21) Appl. No.: 18/735,134

(22) Filed: Jun. 5, 2024

(30) Foreign Application Priority Data
Jun. 7, 2023 (CN) 202310670705.3

(51) Int. Cl. H01L 23/367; H01L 23/00; H01L 23/10; H01L 23/31; H01L 23/498; H01L 25/10

(52) U.S. Cl. CPC H01L 23/367; H01L 23/10; H01L 23/3157; H01L 25/105; H01L 23/49816; H01L 24/16; H01L 24/32; H01L 24/73; H01L 2224/16227; H01L 2224/32225; H01L 2224/73204; H01L 2225/1094

(57) ABSTRACT

The present disclosure discloses a package structure and a manufacturing method thereof. The package structure includes a first substrate, a second substrate, a first chip, a second chip, a heat sink and inter-board connection structures. The second substrate is provided with a first opening penetrating through an upper surface and a lower surface of the second substrate. The first chip is mounted to an upper surface of the first substrate, and the first chip is electrically connected to the first substrate. The second substrate is mounted to the upper surface of the first substrate. The inter-board connection structures are positioned between the lower surface of the second substrate and the upper surface of the first substrate, and the second substrate is electrically connected to the first substrate through the inter-board connection structures.

### CROSS-REFERENCE TO RELATED APPLICATION

This application claims the priority benefit of China application serial no. 202310670705.3, filed on Jun. 7, 2023. The entirety of the above-mentioned patent application is hereby incorporated by reference herein and made a part of this specification.

### TECHNICAL FIELD

The present disclosure relates to the field of semiconductor packaging, and in particular, to a package structure and a manufacturing method thereof.

### BACKGROUND

With the increasing application demands for smartphones, smart wearables, smart manufacturing, assisted driving of automobiles and motor vehicles, and AIoT, terminal products require a small size and low power consumption while maintaining higher performance. In addition to system on chip (SoC) where chip manufacturing sites focuses on advanced silicon technology nodes, system in package (SiP) where packaging and testing manufacturing sites focuses on advanced packaging technology, is also very competitive with low cost, flexibility and high yield. With the increased integration density, SiP has also developed towards 2.5 D and 3D from early 2D packaging forms (such as Multi-Chip Module, MCM).

As a type of three-dimensional (3D) packaging, POP (Package on Package) stacked packaging generally includes an upper substrate and a lower substrate stacked up and down, and each substrate mounted with corresponding semiconductor chips. The power consumption of semiconductor chips during operation generates heat, and excessively high temperature may cause damage to devices and even cause safety hazards in severe cases; therefore, how to effectively improve the heat dissipation of the semiconductor chips, especially the heat dissipation management of those on the lower substrate, is a challenge that urgently needs to be settled in the field.

### SUMMARY

In view of this, the present disclosure provides a package structure, which includes: a first substrate, a second substrate, a first chip, a second chip, a heat sink and inter-board connection structures, where the second substrate is provided with a first opening penetrating through an upper surface and a lower surface of the second substrate;
the first chip is mounted to an upper surface of the first substrate, then the first chip is electrically connected to the first substrate;
the second substrate is mounted to the upper surface of the first substrate, the inter-board connection structures are positioned between the lower surface of the second substrate and the upper surface of the first substrate, and the second substrate is electrically connected to the first substrate through the inter-board connection structures, and the first opening in the second substrate at least exposes a part of the back side of the first chip;
the second chip is mounted to the upper surface of the second substrate, then the second chip is electrically connected to the second substrate; and
the heat sink is mounted to the back side of the first chip through the first opening.

In some embodiments, the first chip has a size larger than that of the first opening, and the first chip has a thickness thinner than that of the inter-board connection structures.

In some embodiments, the surface of the back side beyond the first opening of the first chip is adhered to the lower surface at edge of the first opening of the second substrate by a sealing material, and the first opening exposes the back side surrounded by the sealing materials of the first chip.

In some embodiments, the sealing material completely seals, partially seals, or does not seal the space between the lower surface at edge of the first opening of the second substrate and the surface of the back side beyond the first opening of the first chip.

In some embodiments, a molding compound is filled between the first substrate and the second substrate.

In some embodiments, the heat sink is further mounted to the back side of the second chip.

In some embodiments, the heat sink includes a horizontal heat dissipation area, and its bottom surface protruded with a first vertical pin and a second vertical pin, the bottom end of the first vertical pin is mounted to the back side of the first chip, a part of the bottom surface of the horizontal heat dissipation area is mounted to the back side of the second chip, and the bottom end of the second vertical pin is mounted to the upper surface of the second substrate.

In some embodiments, the first chip has a size smaller than that of the first opening, the first chip has a thickness thicker than or equal to that of the inter-board connection structures, and the back side of the first chip is positioned in the first opening.

In some embodiments, the back side of the first chip is provided with a backside metallization layer, and the heat sink is mounted to the surface of the backside metallization layer through the first opening.

In some embodiments, the inter-board connection structures include one or more of solder ball, cored metal ball, plastic core ball, metal pillar, metal block and 3D interposer, where the 3D interposer can be substrate, PCB, molding package, through-silicon via or through-glass via.

In some embodiments, a third chip and/or a first passive component electrically connected to the first substrate is further mounted onto the upper surface of the first substrate; a fourth chip and/or a second passive component electrically connected to the second substrate is further mounted onto the upper surface of the second substrate; a third passive component electrically connected to the second substrate is further mounted onto the lower surface of the second substrate; and a fourth passive component electrically connected onto the first substrate is further mounted onto the lower surface of the first substrate.

In some embodiments, gap between the first chip and the upper surface of the first substrate and between the second chip and the upper surface of the second substrate are filled with underfill.

The present disclosure further provides a manufacturing method of a package structure, which includes:
providing a first substrate, a second substrate, a first chip and a second chip, where the second substrate is provided with a first opening penetrating through an upper surface and a lower surface of the second substrate;
mounting the first chip to an upper surface of the first substrate, where the first chip is electrically connected to the first substrate;
forming inter-board connection structures on the lower surface of the second substrate;
mounting the second substrate to the upper surface of the first substrate, where the second substrate is electrically connected to the first substrate through the inter-board connection structures, and the first opening in the second substrate at least exposes a part of the back side of the first chip;
mounting the second chip to the upper surface of the second substrate, where the second chip is electrically connected to the second substrate; and
mounting the heat sink to the back side of the first chip through the first opening.

In some embodiments, the first chip has a size larger than that of the first opening, and the first chip has a thickness thinner than that of the inter-board connection structures.

In some embodiments, the surface of the back side beyond the first opening of the first chip is adhered to the lower surface at an edge of the first opening of the second substrate by a sealing material, and the first opening exposes the back side surrounded the sealing materials of the first chip.

In some embodiments, the sealing material completely seals, partially seals, or does not seal the space between the lower surface at edge of the first opening of the second substrate and the surface of the back side beyond the first opening of the first chip.

In some embodiments, the manufacturing method further includes: filling molding compound between the first substrate and the second substrate; and when the sealing material does not seal or partially seals the space between the lower surface at edge of the first opening of the second substrate and the surface of the back side beyond the first opening of the first chip, removing redundant molding compound on the back side below the first opening of the first chip.

In some embodiments, the back side of the first chip is provided with a backside metallization layer, and the heat sink is mounted to the surface of the backside metallization layer through the first opening.

In some embodiments, the heat sink includes a horizontal heat dissipation area, and its bottom surface protruded with a first vertical pin and a second vertical pin, the bottom end of the first vertical pin is mounted to the back side of the first chip, a part of the bottom surface of the horizontal heat dissipation area is mounted to the back side of the second chip, and the bottom end of the second vertical pin is mounted to the upper surface of the second substrate.

In some embodiments, the first chip has a size smaller than that of the first opening, the first chip has a thickness thicker than or equal to that of the inter-board connection structures, and the back side of the first chip is positioned in the first opening.

In some embodiments, the heat sink is further mounted to the back side of the second chip.

In some embodiments, the inter-board connection structures include one or more of solder ball, cored metal ball, plastic core ball, metal pillar, metal block and 3D interposer, where the 3D interposer can be substrate, PCB, molding package, through-silicon via or through-glass via.

In some embodiments, the manufacturing method further includes: mounting a third chip and/or a first passive component onto the upper surface of the first substrate, then electrically connected to the first substrate; mounting a fourth chip and/or a second passive component onto the upper surface of the second substrate, then electrically connected to the second substrate; mounting a third passive component onto the lower surface of the second substrate, then electrically connected to the second substrate; and further mounting a fourth passive component onto the lower surface of the first substrate, then electrically connected to the first substrate.

In some embodiments, the manufacturing method further includes: filling underfill between gap of the first chip and the upper surface of the first substrate and between the second chip and the upper surface of the second substrate.

Compared with the prior art, the technical solutions of the present disclosure have the following advantages:

According to the package structure and the manufacturing method thereof of the present disclosure, the package structure includes: a first substrate, a second substrate, a first chip, a second chip, a heat sink and inter-board connection structures, where the second substrate is provided with a first opening penetrating through an upper surface and a lower surface of the second substrate; the first chip is mounted to an upper surface of the first substrate, and then electrically connected to the first substrate; the second substrate is mounted to the upper surface of the first substrate, the inter-board connection structures are positioned between the lower surface of the second substrate and the upper surface of the first substrate, the second substrate is electrically connected to the first substrate through the inter-board connection structures, and the first opening in the second substrate at least exposes a part of the back side of the first chip; the second chip is mounted to the upper surface of the second substrate, and then electrically connected to the second substrate; and the heat sink is mounted to the back side of the first chip through the first opening. The second substrate is provided with the first opening penetrating through the upper surface and the lower surface of the second substrate, and the heat sink is mounted to the back side of the first chip through the first opening, so that improved the heat dissipation of the first chip assembled between the first substrate and the second substrate; meanwhile, the second substrate is electrically connected to the first substrate through the inter-board connection structures, and particularly when the inter-board connection structures are 3D interposers, thus capable of increasing an interconnection density per unit area and shortening interconnection distance, thereby providing more flexible and changeable system design for smaller package size, higher heat dissipation capacity and higher system performance.

Further, the heat sink is mounted to the back side of the second chip, that is, heat generated by the first chip and the second chip in the package structure can dissipated simultaneously through only one heat sink.

Further, the first chip has a size larger than that of the first opening, and the first chip has a thickness thinner than that of the inter-board connection structures; or the first chip has a size smaller than that of the first opening, the first chip has a thickness thicker than or equal to that of the inter-board connection structures, and the back side of the first chip is positioned in the first opening, then heat dissipation of the first chips with different thicknesses can be improved.

### BRIEF DESCRIPTION OF DRAWINGS

FIGS. 1 to 6 are schematic structural diagrams of a package structure according to some embodiments of the present disclosure.

FIGS. 7 to 9 are schematic structural diagrams of a package structure according to some other embodiments of the present disclosure.

FIGS. 10A to 10E are a structural schematic diagram of a formation process of a package structure according to an embodiment of the present disclosure.

### DETAILED DESCRIPTION OF EMBODIMENTS

The following describes specific embodiments of the present disclosure in detail with reference to accompanying drawings. For ease of description of the embodiments of the present disclosure in detail, schematic diagrams are not partially enlarged according to a general proportion. In addition, the schematic diagrams are merely examples and should not limit the protection scope of the present disclosure. Moreover, the length, width and depth of a three-dimensional space should be included in actual manufacture.

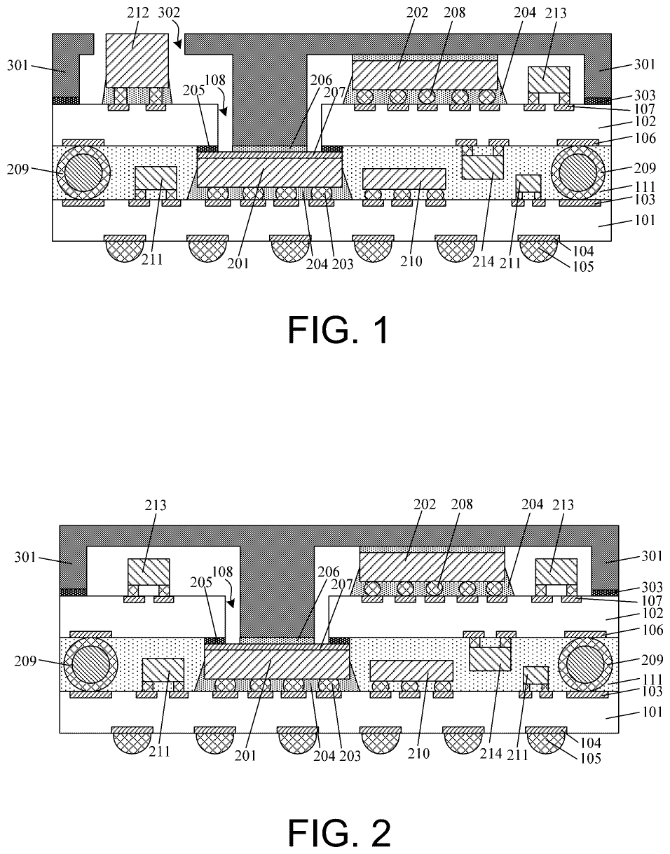

Some embodiments of the present disclosure first provide a package structure, referring to FIG. 1 (or referring to any one of FIGS. 2 to 6), which includes:
a first substrate 101, a second substrate 102, a first chip 201, a second chip 202, a heat sink 301 and inter-board connection structures (209, 215), where the second substrate 102 is provided with a first opening 108 penetrating through an upper surface and a lower surface of the second substrate 102;
the first chip 201 is mounted to an upper surface of the first substrate 101, and the first chip 201 is electrically connected to the first substrate 101;
the second substrate 102 is mounted to the upper surface of the first substrate 101, the inter-board connection structures (209, 215) are positioned between the lower surface of the second substrate 102 and the upper surface of the first substrate 101, the second substrate 102 is electrically connected to the first substrate 101 through the inter-board connection structure (209, 215), and the first opening 108 in the second substrate 102 at least exposes a part of the back side of the first chip 201;
the second chip 202 is mounted to the upper surface of the second substrate 102, and the second chip 202 is electrically connected to the second substrate 102; and
the heat sink 301 is mounted to the back side of the first chip 201 through the first opening 108.

The foregoing package structure includes two substrates stacked up and down, and specifically includes a first substrate 101 and a second substrate 102 positioned above the first substrate 101.

The first substrate 101 is provided with a first line (not shown in the figure), the upper surface and the lower surface of the first substrate 101 are respectively provided with an upper pad 103 and a lower pad 104 which are connected to the first line, the first line, the upper pad 103 and the lower pad 104 are made of metal, and the metal may be one or more of aluminum, nickel, tin, tungsten, platinum, copper, titanium, chromium, tantalum, gold and silver. The first line may be of a single-layer or multi-layer structure, and the first line may include a metal line and a plug or a via interconnection connection (or a through via interconnection structure) electrically connected to the metal line. In an embodiment, the first substrate 101 may be a resin substrate, a ceramic substrate, a glass substrate, a silicon substrate or a printed circuit board (PCB). In an embodiment, surfaces of the upper pad 103 and the lower pad 104 are further provided with solder layers. In an embodiment, a part of the surface of the upper pad 103 and the lower pad 104 is further provided with a protruding metal pillar and a solder layer positioned on a top surface of the metal pillar. The solder layer is made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony, and the metal pillar is made of one or more of aluminum, nickel, tin, tungsten, platinum, copper, titanium, chromium, tantalum, gold and silver.

The second substrate 102 is provided with a second line (not shown in the figure), the upper surface and the lower surface of the second substrate 102 are respectively provided with an upper pad 107 and a lower pad 106 which are connected to the second line, the second line, the upper pad 107 and the lower pad 106 are made of metal, and the metal may be one or more of aluminum, nickel, tin, tungsten, platinum, copper, titanium, chromium, tantalum, gold and silver; the second line may be of a single-layer or multi-layer structure, and the second line may include a metal line and a plug or a via interconnection connection (or a through via interconnection structure) electrically connected to the metal line. In an embodiment, the second substrate 102 may be a resin substrate, a ceramic substrate, a glass substrate, a silicon substrate or a printed circuit board (PCB). In an embodiment, surfaces of the upper pad 107 and the lower pad 106 are further provided with solder layers. In an embodiment, a part of the surface of the upper pad 107 and the lower pad 106 is further provided with a protruding metal pillar and a solder layer positioned on a top surface of the metal pillar. The solder layer is made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony, and the metal pillar is made of one or more of aluminum, nickel, tin, tungsten, platinum, copper, titanium, chromium, tantalum, gold and silver.

The second substrate 102 is further provided with a first opening 108 penetrating through the upper surface and the lower surface of the second substrate 102, and the first opening 108 serves as a channel for mounting the heat sink 301 to the back side of the first chip 201 (mounted to the upper surface of the first substrate 101), so that the heat dissipation of the first chip 201 molded between the first substrate 101 and the second substrate 102 is improved.

The first chip 201 generates heat during operation. In order not to affect the performance of the first chip 201 and the package structure, the heat generated by the first chip 201 needs to be dissipated. The first chip 201 may be a logic chip and a memory chip. In an embodiment, the logic chip may include a gate array, a cell substrate array, an embedded array, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip, a power supply chip or a complementary metal-oxide-semiconductor (CMOS) image sensor. In an embodiment, the memory chip may include a volatile memory chip (such as a dynamic random access memory (DRAM) or a static RAM (SRAM)) or a non-volatile memory chip (such as a flash memory (Flash), a phase change RAM (PCRAM), a magnetoresistive RAM (MRAM), a ferroelectric RAM (FeRAM) or a resistive RAM (ReRAM)).

The first chip 201 is mounted to the upper surface of the first substrate 101. In an embodiment, the first chip 201 includes opposite front and back sides, an integrated circuit (not shown in the figure) is formed in the first chip 201, the front side of the first chip 201 is provided with a pad (not shown in the figure), and the pad is electrically connected to the integrated circuit. In an embodiment, a first solder bump 203 is further formed on the surface of the pad of the first chip 201, and the first solder bump 203 may be made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony.

In an embodiment, when the first chip 201 is mounted (flip-chipped) on the upper surface of the first substrate 101, a pad on the front surface of the first chip 201 is soldered to the upper pad 103 on the upper surface of the first substrate 101 through the first solder bump 203. In other embodiments, the first chip 201 may be mounted face-up on the upper surface of the first substrate 101 through an adhesive layer, and the pad on the front surface of the first chip 201 is electrically connected to the upper pad 103 on the upper surface of the first substrate 101 through a lead or other connection manners.

In an embodiment, referring to any one of FIGS. 1 to 6, the first chip 201 has a size larger than that of the first opening 108, and the first chip 201 has a thickness thinner than that of the inter-board connection structure (209), or the first chip 201 has a thickness thinner than a vertical distance between the upper surface of the first substrate 101 and the lower surface of the second substrate 102.

In an embodiment, the surface of the back side of the first chip 201 outside the first opening is adhered to the lower surface of the second substrate 102 at an edge of the first opening 108 by a sealing material 205, the first opening 108 exposes the back side of the first chip 201 between the sealing materials 205, and the sealing material 205 allows the first substrate 101 and the second substrate 102 to provide a sealed vacuum molding channel at the first opening 108 for forming a molding compound 111 filling a space between the first substrate 101 and the second substrate 102. In an embodiment, the sealing material 205 may be at least one of a metal bonding layer or an adhesive, the adhesive may or may not contain a filler, and the sealing material 205 may completely seal, partially seal, or do not seal a space between the second substrate at the edge of the first opening and the surface of the back side of the first chip outside the first opening. Specifically, in some specific embodiments, when the sealing is complete (referring to FIG. 1, 2, 3, 5 or 6), the sealing material 205 is in a complete circle at a back edge of the first chip 201, which seals the first opening 108 and the space between the first substrate 101 and the second substrate 102, and provides a sealed vacuum molding channel for the molding compound 111 filling the space between the first substrate 101 and the second substrate 102, where the molding compound does not overflow into the first opening 108. In some other specific embodiments, in a case that the sealing is incomplete (referring to FIG. 4, the sealing material 205 is in a shape of a broken ring or a plurality of dots at the back edge of the first chip 201) or is not achieved (referring to FIG. 4), when the space between the first substrate 101 and the second substrate 102 is filled with the molding compound 111, a special-shaped mold matched with the first opening 108 may be used to form a sealed vacuum molding channel, where the molding compound does not overflow into the first opening 108; or a conventional mold may be used to form a sealed vacuum molding channel on the upper surface of the second substrate 102, where the molding compound at the bottom of the first opening 108 on the back side of the first chip 201 needs to be removed from the molded first opening 108 later to provide a thermal conductive channel for the first chip 201 to directly dissipate heat outward.

In an embodiment, the surface of the back side of the first chip 201 is further provided with a backside metallization layer 207, the backside metallization layer 207 is beneficial to improving the heat dissipation efficiency, and the heat sink 301 is mounted to the surface of the backside metallization layer 207 through the first opening 108. In an embodiment, the backside metallization layer 207 is made of thermal conductive metal, and the thermal conductive metal may be one or more of aluminum, nickel, tin, tungsten, platinum, copper, titanium, chromium, tantalum, gold and silver.

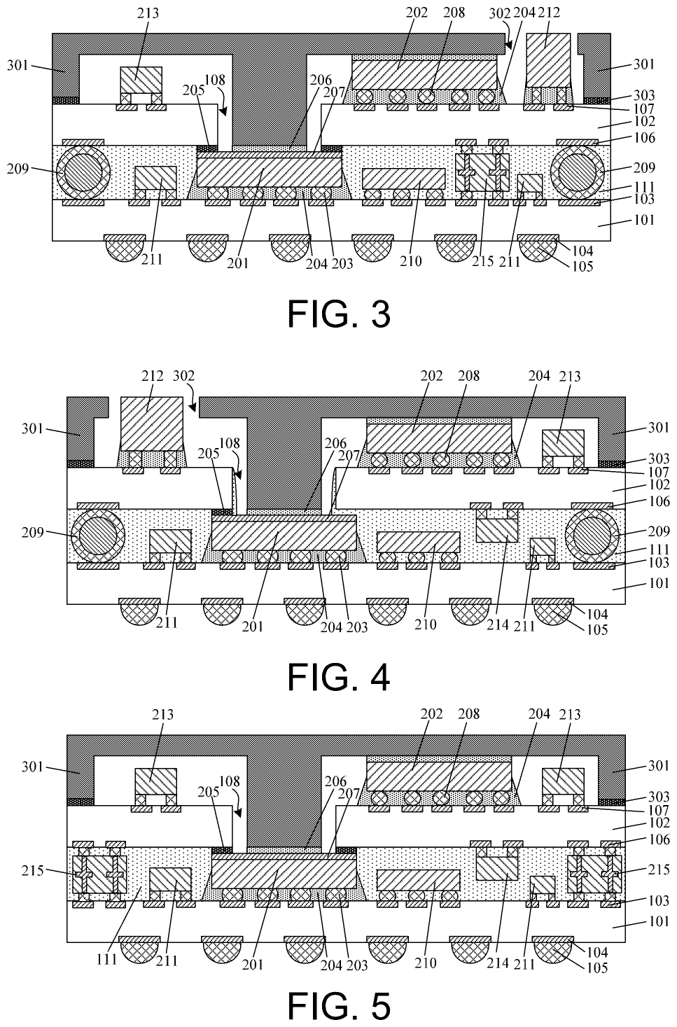

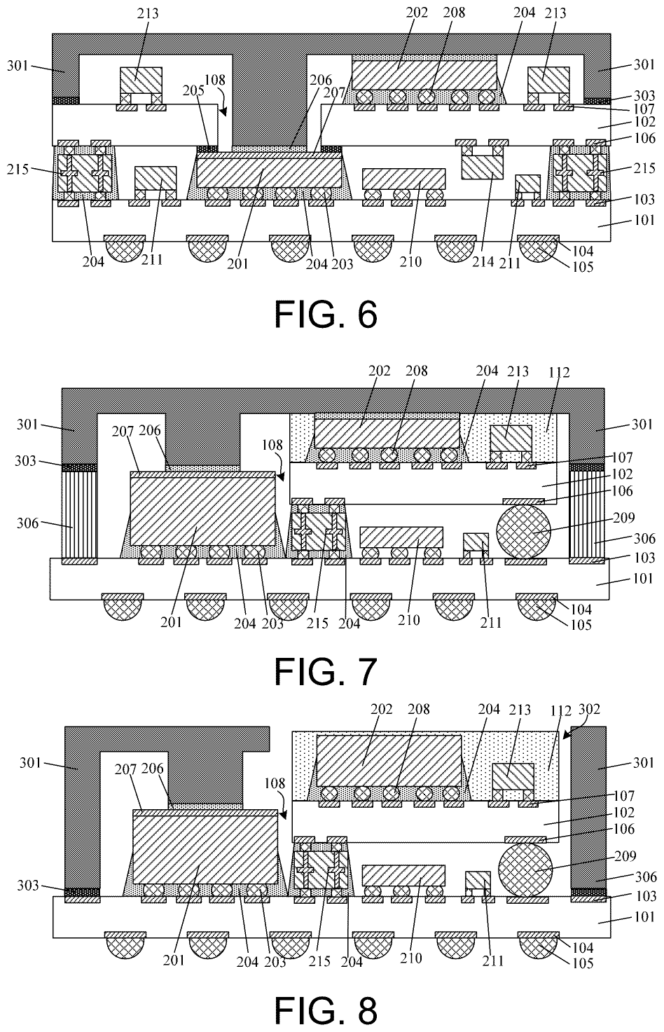

The first substrate 101 is electrically connected to the second substrate 102 through inter-board connection structures (209, 215), and the inter-board connection structures are also used to support the first substrate 101 and the second substrate 102 in the packaging process. The inter-board connection structures include one or more of a solder ball, a cored metal ball, a plastic core ball, a metal pillar, a metal block, a substrate, a PCB, a plastic package, a through-silicon via or a through-glass via. Specifically, in some specific embodiments, referring to FIG. 1, 2 or 4, the inter-board connection structure (209) is a cored metal ball. The cored metal ball may include a core and a metal outer layer covering the core, the core may be made of plastics or metal, and the metal outer layer is made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony. In some other specific embodiments, referring to FIG. 3, the inter-board connection structures (209, 215) include a cored metal ball and a 3D interposer, where the inter-board connection structure (209) is a cored metal ball, and the inter-board connection structure (215) is a 3D interposer. In still some other embodiments, referring to FIG. 5 or 6, the inter-board connection structure (215) is a 3D interposer. The 3D interposer is one or more of substrate, PCB, molding package, through-silicon via or through-glass via, the 3D interposer is provided with a third line, and an upper surface and a lower surface of the 3D interposer are respectively provided with an upper pad and a lower pad which are electrically connected to the third line. A vertical distance between the first substrate 101 and the second substrate 201 is maintained by a combination of the foregoing various inter-board connection structures. Furthermore, the 3D interposer shortens the interconnection distance while improving the interconnection density of the package body.

In an embodiment, a third chip 210 and/or a first passive component 211 electrically connected to the first substrate 101 are further mounted onto the upper surface of the first substrate 101. Specifically, only the third chip 210 or the first passive component 211 electrically connected to the first substrate 101 may be mounted onto the upper surface of the first substrate 101, or the third chip 210 and the first passive component 211 electrically connected to the first substrate 101 may be simultaneously mounted onto the upper surface of the first substrate 101. The third chip 210 and the first passive component 211 have a thickness thinner than the vertical distance between the first substrate 101 and the second substrate 102, and the mounting numbers of the third chips 210 and the first passive components 211 are adjusted based on an actual requirement. In an embodiment, the third chip 210 includes an analog-to-digital conversion chip and/or a digital-to-analog conversion chip, and the first passive component 211 may be one or more of a resistor, a capacitor and an inductor. It should be noted that, in other embodiments, the third chip and/or first passive component may not be mounted onto the upper surface of the first substrate 101.

In an embodiment, an external connection bump 105 connected to a part of the lower pad 104 is further formed on the lower surface of the first substrate 101, the external connection bump 105 is used to connect an external device, and the external connection bump 105 is a solder bump or includes a metal pillar and a solder layer on a top of the metal pillar. In another embodiment, a (fourth) passive component (not shown in the figure) electrically connected to a part of the lower pad 104 is further mounted onto the lower surface of the first substrate 101, and the (fourth) passive component may be one or more of a resistor, a capacitor and an inductor. It should be noted that, in other embodiments, the (fourth) passive component may not be mounted onto the lower surface of the first substrate 101.

In an embodiment, referring to any one of FIGS. 1 to 6, a space between the first chip 201 and the first substrate 101 is further filled with an underfill 204. The underfill 204 is made of a silicon-based resin material, a thermoplastic resin material, a thermally cured resin material or an ultraviolet cured resin material. The underfill 204 may be formed using a dispensing process. It should be noted that, in other embodiments, a space between the first chip 201 and the first substrate 101 may be filled with a molding compound instead of an underfill.

In an embodiment, referring to any one of FIGS. 1 to 5, a space between the first substrate 101 and the second substrate 102 may be filled with a molding compound 111 to protect devices between the first substrate 101 and the second substrate 102. The molding compound 111 may be made of epoxy resin, polyimide resin, benzocyclobutene resin or polybenzoxazole resin, and the forming process may be an injection molding process or a transfer molding process. In another embodiment, referring to FIG. 6, the space between the first substrate 101 and the second substrate 102 may not be filled with a mold compound.

The second chip 202 is mounted to the upper surface of the second substrate 102, the second chip 202 also generates heat during operation, and in order not to affect the performance of the first chip 201 and the package structure, the heat generated by the second chip 202 needs to be dissipated, in the present disclosure, the heat sink 301 is further mounted to the back side of the second chip 202, that is, the heat generated by the first chip 201 and the heat generated by the second chip 202 in the package structure are dissipated simultaneously through one heat sink 301.

The second chip 202 may be a logic chip and a memory chip. In an embodiment, the logic chip may include a gate array, a cell substrate array, an embedded array, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip, a power supply chip or a complementary metal-oxide-semiconductor (CMOS) image sensor. In an embodiment, the memory chip may include a volatile memory chip (such as a dynamic random access memory (DRAM) or a static RAM (SRAM)) or a non-volatile memory chip (such as a flash memory (Flash), a phase change RAM (PCRAM), a magnetoresistive RAM (MRAM), a ferroelectric RAM (FeRAM) or a resistive RAM (ReRAM)).

In an embodiment, the second chip 202 includes opposite front and back sides, an integrated circuit (not shown in the figure) is formed in the second chip 202, the front side of the second chip 202 is provided with a pad (not shown in the figure), and the pad is electrically connected to the integrated circuit. In an embodiment, a second solder bump 208 is further formed on the surface of the pad of the second chip 202, and the second solder bump 208 may be made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony.

In an embodiment, when the second chip 202 is mounted (flip-chipped) on the upper surface of the second substrate 102, a pad on the front surface of the second chip 202 is soldered to the upper pad 107 on the upper surface of the second substrate 102 through the second solder bump 208. In other embodiments, the second chip may be mounted face-up on the upper surface of the second substrate 102 through an adhesive layer, and the pad on the front surface of the second chip 202 is electrically connected to the upper pad 107 on the second substrate 102 through a lead or other connection structures.

The heat sink 301 is used to release or dissipate heat generated by the first chip 201 and the second chip 202 to control the first chip 201 and the second chip 202 in a proper temperature range. The heat sink 301 is made of a material with high thermal conductivity. In an embodiment, the material with high thermal conductivity includes metal (such as copper, aluminum, gold, nickel, steel or stainless steel) or a carbon-containing material (such as graphite, graphene or carbon nanotubes).

In an embodiment, the heat sink 301 includes a horizontal heat dissipation area, and a first vertical pin and a second vertical pin protruding from a bottom surface of the horizontal heat dissipation area, the first vertical pin passes through the first opening 108 in the second substrate 102 and the bottom end of the first vertical pin is mounted to the back side of the first chip 201, a part of the bottom surface of the horizontal heat dissipation area is mounted to the back side of the second chip 202, and the bottom end of the second vertical pin is mounted to the upper surface of the second substrate 102. The package structure of the present disclosure can simultaneously dissipate the heat of the first chip 201 mounted onto the first substrate 101 and the heat of the second chip 202 mounted onto the second substrate 102 through one heat sink 301.

In an embodiment, the bottom end of the first vertical pin of the heat sink 301 is mounted to the back side of the first chip 201 through the thermal interface material layer 206, a part of the bottom surface of the horizontal heat dissipation area of the heat sink 301 is also mounted to the back side of the second chip 202 through the same or different thermal interface material layer 206, and the bottom end of the second vertical pin of the heat sink 301 is mounted to the upper surface of the second substrate 102 through the adhesive layer 303. The thermal interface material (TIM) layer 206 can effectively reduce thermal contact resistance between different structures and quickly transfer heat generated by the first chip 201 and the second chip 202 to the heat sink 301. The thermal interface material layer may be made of one or more of thermal conductive silicone, thermal conductive gel, a thermal interface material layer or a metal-based thermal interface material. The adhesive layer 303 is made of an adhesive glue, and the adhesive glue may or may not contain a filler.

In some embodiments, a fourth chip 212 and/or a second passive component 213 electrically connected to the second substrate 102 are further mounted onto the upper surface of the second substrate 102; and a third passive component 214 electrically connected to the second substrate 102 is further mounted to the lower surface of the second substrate 102. In a specific embodiment, referring to FIG. 1, 3 or 4, a fourth chip 212 and a second passive component 213 electrically connected to the second substrate 102 are further mounted onto the upper surface of the second substrate 102, and a third passive component 214 electrically connected to the second substrate 102 may also be mounted onto the lower surface of the second substrate 102 (in an embodiment, referring to FIG. 3, a third passive component 214 may also not be mounted onto the lower surface of the second substrate 102). In another specific embodiment, referring to FIG. 2, 5 or 6, only a second passive component 213 electrically connected to the second substrate 102 is further mounted onto the upper surface of the second substrate 102, and a third passive component 214 electrically connected to the second substrate 102 is further mounted onto the lower surface of the second substrate 102. The mounting numbers of the fourth chips 212, the second passive components 213 and the third passive components 214 are adjusted based on an actual requirement.

In an embodiment, referring to FIG. 1, 3 or 4, when the fourth chip 212 or the second passive component 213 mounted onto the upper surface of the second substrate 102 have a high height, to reduce a thickness of the package structure as much as possible, the heat sink 301 is further provided with a second opening 302 penetrating through the upper surface and the lower surface of the heat sink, and the back side of the fourth chip 212 or the second passive component 213 may extend into the second opening 302.

In another embodiment, a height of the fourth chip 212 and a height of the second passive component 213 are both thinner than a vertical distance between the bottom surface of the heat sink and the upper surface of the second substrate 102, and the heat sink 301 does not need to be opened.

In an embodiment, a space between the second chip 202 and the upper surface of the second substrate 102 is filled with an underfill 204.

Some other embodiments of the present disclosure further provide a package structure (the main differences between this embodiment and the foregoing embodiment are that a thickness of the first chip is different, and a size of the first opening 108 formed in the second substrate 102 is different; and the limitations of the same or similar parts in this embodiment and the foregoing embodiment are not described herein again. For detail, referring to the limitations of the corresponding parts in the foregoing embodiment). Referring to FIG. 7, 8 or 9, the package structure includes a first substrate 101, a second substrate 102, a first chip 201, a second chip 202, a heat sink 301 and inter-board connection structures (209, 215), where the second substrate 102 is provided with a first opening 108 penetrating through an upper surface and a lower surface of the second substrate 102; the first chip 201 has a size thinner than that of the first opening 108, and the first chip 201 has a thickness larger than or equal to that of the inter-board connection structures (209, 215); the first chip 201 is mounted to an upper surface of the first substrate 101, the first chip 201 is electrically connected to the first substrate 101, and the back side of the first chip 201 is positioned in the first opening 108; the second substrate 102 is mounted to the upper surface of the first substrate 101, the inter-board connection structures (209, 215) are positioned between the lower surface of the second substrate 102 and the upper surface of the first substrate 101, the second substrate 102 is electrically connected to the first substrate 101 through the inter-board connection structure (209, 215); the second chip 202 is mounted to the upper surface of the second substrate 102, and the second chip 202 is electrically connected to the second substrate 102; and the heat sink 301 is mounted to the back side of the first chip 201 through the first opening 108.

In an embodiment, referring to FIG. 7, the heat sink 301 may also be mounted to the back side of the second chip 202. The heat sink 301 may include a horizontal heat dissipation area, and a first vertical pin and a second vertical pin protruding from a bottom surface of the horizontal heat dissipation area, where the first vertical pin passes through the first opening 108 in the second substrate 102 and the bottom end of the first vertical pin is mounted to the back side of the first chip 201 (through a thermal interface material 206), a part of the bottom surface of the horizontal heat dissipation area is mounted to the back side of the second chip 202, and the bottom end of the second vertical pin is mounted to a top surface of a pillar 306 positioned on the upper surface of the first substrate 101 (through an adhesive layer 303). The pillar 306 may be made of metal.

In another embodiment, referring to FIG. 8, the heat sink 301 may include a horizontal heat dissipation area, and a first vertical pin and a second vertical pin protruding from a bottom surface of the horizontal heat dissipation area, where the first vertical lead is mounted to the back side of the first chip 201 through a thermal interface material 206, the bottom end of the second vertical pin is mounted to the upper surface of the first substrate 101 (through an adhesive layer 303), and the horizontal heat dissipation area is provided with a second opening 302 exposing the back side of the second chip 202.

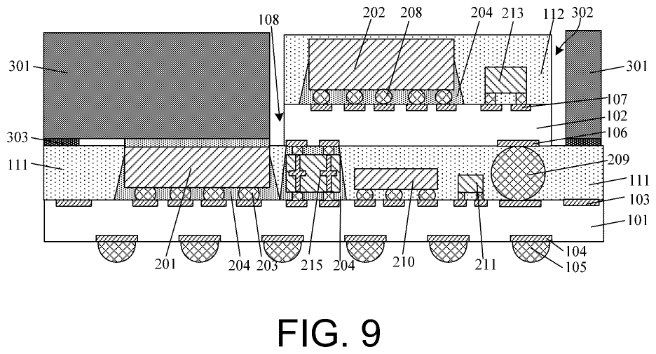

In another embodiment, referring to FIG. 9, the heat sink 301 is not mounted to the second chip 202, and the heat sink 301 is provided with a second opening 302 to expose the back side of the second chip 202. In addition to a part of the heat sink 301 mounted to the back side of the first chip 201 (through a thermal interface material 206), other parts of the heat sink 301 may be mounted to the surface of a molding compound 111 filled between the first substrate 101 and the second substrate 101 (through an adhesive layer 303).

In an embodiment, a third chip 210 and/or a first passive component 211 electrically connected to the first substrate 101 is further mounted onto the upper surface of the first substrate 101; a fourth chip (not shown in the figure) and/or a second passive component 213 electrically connected to the second substrate 102 is further mounted onto the upper surface of the second substrate 102; a third passive component (not shown in the figure) electrically connected to the second substrate 102 is further mounted onto the lower surface of the second substrate 102; and a fourth passive component (not shown in the figure) electrically connected to the first substrate 101 is further mounted onto the lower surface of the first substrate 101. It should be noted that, in other embodiments, a third chip and/or a second passive component may not be mounted to the upper surface of the first substrate 101; a fourth chip and/or a second passive component may not be mounted to the upper surface of the second substrate 102; a third passive component may not be mounted to the lower surface of the second substrate 102; and a fourth passive component may not be mounted to the lower surface of the first substrate 101.

In an embodiment, an underfill 204 is filled between the first chip 201 and the upper surface of the first substrate 101 and between the second chip 202 and the upper surface of the second substrate 102.

In an embodiment, a second molding compound 112 molding the second chip 202 and the second passive component 213 is formed on the upper surface of the second substrate 102.

In an embodiment, the inter-board connection structures (209, 215) are one or more of solder ball, cored metal ball, plastic core ball, metal pillar, metal block and 3D interposer. In a specific embodiment, the inter-board connection structure (209) is a solder ball. The inter-board connection structure (215) is a 3D interposer.

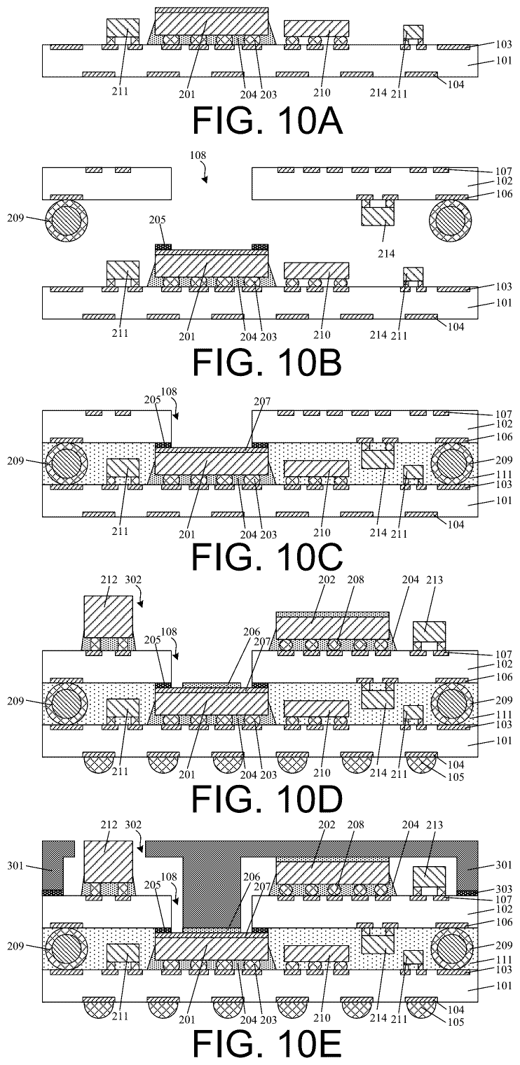

An embodiment of the present disclosure further provides a manufacturing method of a package structure (the limitations of the same or similar parts in this manufacturing method embodiment and the foregoing package structure embodiment are not described herein again, and for detail, referring to the limitations of the corresponding parts in the foregoing package structure embodiment), referring to FIG. 10A to 10E, which includes:
providing a first substrate 101, a second substrate 102, a first chip 201 and a second chip 202, where the second substrate 102 is provided with a first opening 108 penetrating through an upper surface and a lower surface of the second substrate 102 (referring to FIG. 10A and FIG. 10B);
the first chip 201 is mounted to an upper surface of the first substrate 101, and the first chip 201 is electrically connected to the first substrate 101 (referring to FIG. 10A);
forming an inter-board connection structure (209) on the lower surface of the second substrate 102 (referring to FIG. 10B);
mounting the second substrate 102 to the upper surface of the first substrate 101, where the second substrate 201 is electrically connected to the first substrate 101 through the inter-board connection structure (209), and the first opening 108 in the second substrate 201 at least exposes a part of the back side of the first chip 201 (referring to FIG. 10C);
mounting the second chip 202 to the upper surface of the second substrate 102 (referring to FIG. 10D); and
mounting the heat sink 301 to the back side of the first chip 201 through the first opening 108 (referring to FIG. 10E).

In an embodiment, the first chip 201 has a size larger than that of the first opening 108, and the first chip 201 has a thickness thinner than that of the inter-board connection structure (209).

In an embodiment, the surface of the back side of the first chip 201 outside the first opening is adhered to the lower surface of the second substrate 102 at an edge of the first opening 108 by a sealing material 205, and the first opening 108 exposes the back side of the first chip 201 between the sealing materials 205.

In an embodiment, the sealing material 205 completely seals, partially seals, or does not seal the space between the second substrate 102 at the edge of the first opening 108 and the surface of the back side of the first chip 201 outside the first opening 108.

In an embodiment, forming the sealing material 205 and electrically connecting the second substrate 201 to the first substrate through the inter-board connection structure 209 further includes: filling a molding compound 111 between the first substrate 101 and the second substrate 102; and when the sealing material 205 does not seal or partially seals a space between the second substrate 102 at the edge of the first opening 108 and the surface of the back side of the first chip 101 outside the first opening, removing redundant molding compound on the back side of the first chip 201 below the first opening 108.

In an embodiment, the back side of the first chip 201 is provided with a backside metallization layer 207, and the heat sink 301 is mounted to the surface of the backside metallization layer 207 through the first opening 108.

In an embodiment, the heat sink 301 is further mounted to the back side of the second chip 202. In an embodiment, the heat sink 301 includes a horizontal heat dissipation area, and its bottom surface protruded with a first vertical pin and a second vertical pin, the bottom end of the first vertical pin is mounted to the back side of the first chip 201, a part of the bottom surface of the horizontal heat dissipation area is mounted to the back side of the second chip 202, and the bottom end of the second vertical pin is mounted to the upper surface of the second substrate 102.

In an embodiment, the inter-board connection structure is one or more of solder ball, cored metal ball, plastic core ball, metal pillar, metal block and 3D interposer. In a specific embodiment, the inter-board connection structure (209) is a cored metal ball. The inter-board connection structure (215) is a 3D interposer.

In another embodiment, the first chip 101 has a size thinner than that of the first opening 108, the first chip 101 has a thickness larger than or equal to that of the inter-board connection structures (209, 215), and the back side of the first chip is positioned in the first opening 108 (referring to FIG. 7, 8 or 9).

In an embodiment, the manufacturing method further includes: mounting a third chip 210 and/or a first passive component 211 electrically connected to the first substrate 101 on the upper surface of the first substrate 101 (referring to FIG. 10A); mounting a fourth chip 212 and/or a second passive component 213 electrically connected to the second substrate 102 on the upper surface of the second substrate 102 (referring to FIG. 10D); and mounting a third passive component 214 electrically connected to the second substrate 102 on the lower surface of the second substrate 102 (referring to FIG. 10B).

In an embodiment, the manufacturing method further includes: filling an underfill 204 between the first chip 201 and the upper surface of the first substrate 101 and between the second chip 202 and the upper surface of the second substrate 102 (referring to FIG. 10A and FIG. 10D).

The present disclosure has been described with reference to the preferred embodiment, which is not intended to be limited thereto. Those skilled in the art can make possible variations and modifications to the present disclosure using the disclosed methods and technical contents without departing from the spirit and scope of the present disclosure; and therefore, any simple modifications, equivalent changes and modifications made to the above embodiments according to the technical spirit of the present disclosure without departing from the content of the technical solutions of the present disclosure shall fall within the protection scope of the technical solutions of the present disclosure.

What is claimed is:

1. A package structure, comprising a first substrate, a second substrate, a first chip, a second chip, a heat sink and an inter-board connection structure, wherein
the second substrate is provided with a first opening penetrating through an upper surface and a lower surface of the second substrate;
the first chip is mounted to an upper surface of the first substrate, and the first chip is electrically connected to the first substrate;
the second substrate is mounted to the upper surface of the first substrate, the inter-board connection structure is positioned between the lower surface of the second substrate and the upper surface of the first substrate, the second substrate is electrically connected to the first substrate through the inter-board connection structure, and the first opening in the second substrate at least exposes a part of the back side of the first chip;
the second chip is mounted to the upper surface of the second substrate, and the second chip is electrically connected to the second substrate; and
the heat sink passes through the first opening and is mounted to the back side of the first chip through the first opening.

2. The package structure according to claim 1, wherein the first chip has a size larger than that of the first opening, and the first chip has a thickness thinner than that of the inter-board connection structure.

3. The package structure according to claim 2, wherein the surface of the back side of the first chip outside the first opening is adhered to the lower surface of the second substrate at an edge of the first opening through sealing material, and the first opening exposes the back side of the first chip between the sealing material.

4. The package structure according to claim 3, wherein the sealing material completely seals, partially seals, or does not seal the space between the second substrate at the edge of the first opening and the surface of the back side of the first chip outside the first opening.

5. The package structure according to claim 4, wherein a molding compound is filled between the first substrate and the second substrate.

6. The package structure according to claim 2, wherein the heat sink is further mounted to the back side of the second chip.

7. The package structure according to claim 6, wherein the heat sink comprises a horizontal heat dissipation area, and a first vertical pin and a second vertical pin protruding from a bottom surface of the horizontal heat dissipation area, the bottom end of the first vertical pin is mounted to the back side of the first chip, a part of the bottom surface of the horizontal heat dissipation area is mounted to the back side of the second chip, and the bottom end of the second vertical pin is mounted to the upper surface of the second substrate.

8. The package structure according to claim 1, wherein the first chip has a size thinner than that of the first opening, the first chip has a thickness larger than or equal to that of the inter-board connection structure, and the back side of the first chip is positioned in the first opening.

9. The package structure according to claim 1, wherein the back side of the first chip is provided with a backside metallization layer, and the heat sink passes through the first opening and is mounted to the surface of the backside metallization layer.

10. The package structure according to claim 1, wherein the inter-board connection structure comprises one or more of solder ball, cored metal ball, plastic core ball, metal pillar, metal block and 3D interposer, and wherein the 3D interposer is substrate, PCB, molding package, through-silicon via or through-glass via.

11. The package structure according to claim 1, wherein a third chip or a first passive component electrically connected to the first substrate is further mounted onto the upper surface of the first substrate; a fourth chip or a second passive component electrically connected to the second substrate is further mounted onto the upper surface of the second substrate; a third passive component electrically connected to the second substrate is further mounted onto the lower surface of the second substrate; and a fourth passive component electrically connected to the first substrate is further mounted onto the lower surface of the first substrate.

12. A manufacturing method of a package structure, comprising:
providing a first substrate, a second substrate, a first chip and a second chip, wherein the second substrate is provided with a first opening penetrating through an upper surface and a lower surface of the second substrate;
mounting the first chip to an upper surface of the first substrate, wherein the first chip is electrically connected to the first substrate;
forming an inter-board connection structure on the lower surface of the second substrate;
mounting the second substrate to the upper surface of the first substrate, wherein the second substrate is electrically connected to the first substrate through the inter-board connection structure, and the first opening in the second substrate at least exposes a part of the back side of the first chip;
mounting the second chip to the upper surface of the second substrate, wherein the second chip is electrically connected to the second substrate; and
mounting the heat sink to the back side of the first chip with the heat sink passing through the first opening.

13. The manufacturing method of the package structure according to claim 12, wherein the first chip has a size larger than that of the first opening, and the first chip has a thickness thinner than that of the inter-board connection structure.

14. The manufacturing method of the package structure according to claim 13, wherein the surface of the back side of the first chip outside the first opening is adhered to the lower surface of the second substrate at an edge of the first opening through sealing material, and the first opening exposes the back side of the first chip between the sealing material.

15. The manufacturing method of the package structure according to claim 14, wherein the sealing material completely seals, partially seals, or does not seal a space between the second substrate at the edge of the first opening and the surface of the back side of the first chip outside the first opening.

16. The manufacturing method of the package structure according to claim 15, further comprising filling a molding compound between the first substrate and the second substrate; and when the sealing material does not seal or partially seals the space between the second substrate at the edge of the first opening and the surface of the back side of the first chip outside the first opening, removing redundant molding compound on the back side of the first chip below the first opening.

17. The manufacturing method of the package structure according to claim 13, wherein the back side of the first chip is provided with a backside metallization layer, and the heat sink passes through the first opening and is mounted to the surface of the backside metallization layer.

18. The manufacturing method of the package structure according to claim 17, wherein the heat sink comprises a horizontal heat dissipation area, and a first vertical pin and a second vertical pin protruding from a bottom surface of the horizontal heat dissipation area, the bottom end of the first vertical pin is mounted to the back side of the first chip, a part of the bottom surface of the horizontal heat dissipation area is mounted to the back side of the second chip, and the bottom end of the second vertical pin is mounted to the upper surface of the second substrate.

19. The manufacturing method of the package structure according to claim 13, wherein the first chip has a size thinner than that of the first opening, the first chip has a thickness larger than or equal to that of the inter-board connection structure, and the back side of the first chip is positioned in the first opening.

20. The manufacturing method of the package structure according to claim 12, wherein the heat sink is further mounted to the back side of the second chip.
